(19) United States
(12) Patent Application Publication
(10) Pub. No.: US 2026/0310094 A1
(43) Pub. Date: Oct. 8, 2026

(54) MANUFACTURING METHOD OF REDISTRIBUTION LAYER

(71) Applicant: Shanghai AVIC Optoelectronics Co., Ltd., Shanghai (CN)

(72) Inventors: Nobuya SEKO, Kawasaki (JP); Noriyuki ITOU, Kawasaki (JP); Akira SUZUKI, Kawasaki (JP)

(73) Assignee: Shanghai AVIC Optoelectronics Co., Ltd., Shanghai (CN)

(21) Appl. No.: 19/635,922

(22) Filed: Apr. 1, 2026

(30) Foreign Application Priority Data
Apr. 8, 2025 (JP) 2025-063690

(51) Int. Cl. G03F 7/00; G03F 7/20; H10W 70/00; H10W 70/05

(52) U.S. Cl. CPC G03F 7/70466; G03F 7/2022; H10W 70/05; H10W 70/099

(57) ABSTRACT

A manufacturing method of a redistribution layer includes a first exposure step of exposing a negative photosensitive material layer on a first main surface of a support substrate with light in a predetermined pattern, a second exposure step of exposing the negative photosensitive material layer with light over its entire surface from the side of a second main surface of the support substrate, a development step of developing the exposed negative photosensitive material layer to form a first insulating layer having a recessed pattern on a second main surface, and a first wiring layer forming step of forming a first wiring layer on the second main surface of the first insulating layer, and a separation step of irradiating the first insulating layer with light from the side of the second main surface of the support substrate to separate the first insulating layer from the support substrate.

### CROSS-REFERENCE TO RELATED APPLICATIONS

This application claims the benefit of Japanese Patent Application No. 2025-063690, filed on Apr. 8, 2025, the entire disclosure of which is incorporated by reference herein.

### FIELD OF THE INVENTION

The present disclosure relates to a manufacturing method of a redistribution layer.

### BACKGROUND OF THE INVENTION

As package technologies for semiconductor chips to cope with the thinning and higher integration of wiring substrates on which the semiconductor chips are mounted, technologies such as fan-out wafer level package (FOWLP) technology and fan-out panel level package (FOPLP) technology are known. As one example of FOWLP technology, a manufacturing method is known in which a redistribution layer is formed by laminating an insulating layer and a wiring layer on a support substrate, and the redistribution layer is then separated from the support substrate (for example, Japanese U.S. Pat. No. 5,042,297 and Japanese Patent No. 7208011).

In the manufacturing method in which the redistribution layer is separated from the support substrate, a release layer is provided between the support substrate and the redistribution layer in order to facilitate the separation of the redistribution layer from the support substrate. For example, in Japanese U.S. Pat. No. 7,208,011, a laminated sheet including a base material, a release layer, and a metal layer in this order is prepared, a first wiring layer is formed on the surface of the metal layer, and an insulating layer and an n-th wiring layer are alternately formed on the surface on which the first wiring layer has been formed, to obtain a multilayer laminate. In Japanese U.S. Pat. No. 7,208,011, a reinforcing sheet is provided on the multilayer laminate, and the base material is then separated from the metal layer at the release layer.

In the manufacturing methods disclosed in Japanese U.S. Pat. No. 5,042,297 and Japanese U.S. Pat. No. 7,208,011, the release layer is provided in addition to the insulating layer and the wiring layer, resulting in an increased material cost for the release layer as well as an increased number of manufacturing steps. Therefore, in the manufacturing methods disclosed in Japanese U.S. Pat. No. 5,042,297 and Japanese U.S. Pat. No. 7,208,011, there is a risk that the manufacturing cost may increase.

### SUMMARY OF THE INVENTION

A manufacturing method of a redistribution layer of the present disclosure includes:
a photosensitive layer forming step of forming a negative photosensitive material layer on a first main surface of a light-transmitting support substrate;
a first exposure step of exposing the negative photosensitive material layer formed on the first main surface of the support substrate with light in a predetermined pattern;
a second exposure step of exposing the negative photosensitive material layer formed on the first main surface of the support substrate with light over an entire surface of the negative photosensitive material layer from a side of a second main surface of the support substrate opposite to the first main surface;
a development step of developing the negative photosensitive material layer exposed with light in the first exposure step and the second exposure step, and thereby forming a first insulating layer on the first main surface of the support substrate, the first insulating layer having a recessed pattern corresponding to the predetermined pattern on a second main surface of the first insulating layer, the second main surface of the first insulating layer being opposite to a first main surface of the first insulating layer opposing the first main surface of the support substrate;
a first wiring layer forming step of forming, based on the recessed pattern, a first wiring layer on the second main surface of the first insulating layer; and
a separation step of irradiating the first insulating layer with light to be absorbed by the first insulating layer from the side of the second main surface of the support substrate, and thereby separating, from the support substrate, the first insulating layer on which the first wiring layer is formed.

It is to be understood that both the foregoing general description and the following detailed description are exemplary and explanatory and are not restrictive of this disclosure.

### BRIEF DESCRIPTION OF DRAWINGS

A more complete understanding of this application can be obtained when the following detailed description is considered in conjunction with the following drawings, in which:

FIG. 1 is a cross-sectional view illustrating a redistribution layer according to Embodiment 1;

FIG. 2 is a cross-sectional view illustrating a semiconductor device according to Embodiment 1;

FIG. 3 is a flowchart illustrating a manufacturing method of the redistribution layer according to Embodiment 1;

FIG. 4 is a cross-sectional view illustrating a support substrate and a negative photosensitive material layer according to Embodiment 1;

FIG. 5 is a schematic view for describing a first exposure step according to Embodiment 1;

FIG. 6 is a diagram illustrating an exposure sensitivity curve of a negative photosensitive material according to Embodiment 1;

FIG. 7 is a schematic view for describing a second exposure step according to Embodiment 1;

FIG. 8 is a cross-sectional view illustrating the support substrate and a first insulating layer according to Embodiment 1;

FIG. 9 is a diagram illustrating the relationship between an exposure dose in the second exposure step and a thickness of the first insulating layer at a position where a recess is formed, according to Embodiment 1;

FIG. 10 is a cross-sectional view illustrating the support substrate, the first insulating layer, and first wiring layers according to Embodiment 1;

FIG. 11 is a diagram for describing a first wiring layer forming step according to Embodiment 1;

FIG. 12 is a diagram for describing the first wiring layer forming step according to Embodiment 1;

FIG. 13 is a diagram for describing the first wiring layer forming step according to Embodiment 1;

FIG. 14 is a diagram for describing an upper layer forming step according to Embodiment 1;

FIG. 15 is a diagram for describing a terminal protection layer forming step according to Embodiment 1;

FIG. 16 is a diagram for describing a mold forming step according to Embodiment 1;

FIG. 17 is a diagram for describing a separation step according to Embodiment 1;

FIG. 18 is a diagram for describing the separation step according to Embodiment 1;

FIG. 19 is a cross-sectional view illustrating a support substrate, first insulating layers, and first wiring layers according to a comparative example;

FIG. 20 is a diagram for describing an external connection terminal forming step according to Embodiment 1;

FIG. 21 is a diagram for describing a first exposure step according to Embodiment 2;

FIG. 22 is a cross-sectional view illustrating a redistribution layer according to Embodiment 3;

FIG. 23 is a flowchart illustrating a manufacturing method of the redistribution layer according to Embodiment 3;

FIG. 24 is a schematic view for describing a second exposure step according to a modified example; and

FIG. 25 is a cross-sectional view illustrating a redistribution layer according to a modified example.

### DETAILED DESCRIPTION OF THE INVENTION

Hereinafter, a manufacturing method of a redistribution layer and a semiconductor device including the redistribution layer according to embodiments are described with reference to the drawings.

### Embodiment 1

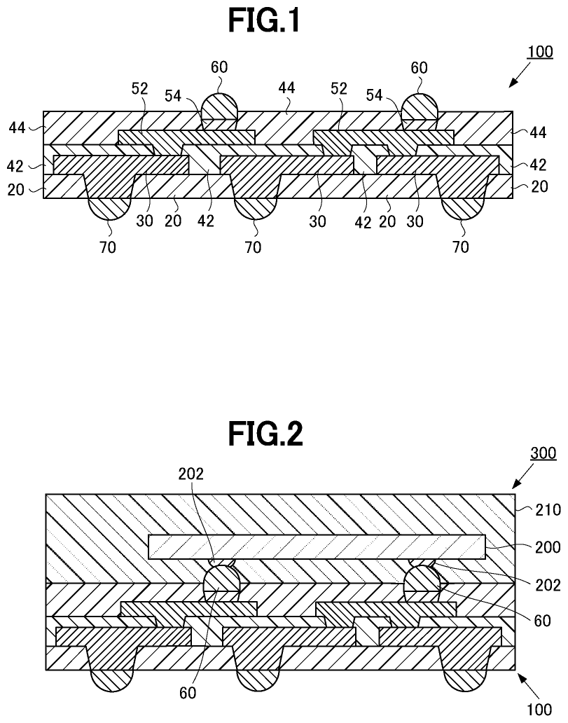

A manufacturing method of a redistribution layer 100 and a semiconductor device 300 including the redistribution layer 100 according to the present embodiment are described with reference to FIGS. 1 to 20. The redistribution layer 100 is used, for example, in packaging of a semiconductor chip 200. The semiconductor device 300 is a fan-out type semiconductor device. 10 First, the configurations of the redistribution layer 100 and the semiconductor device 300 are described.

As illustrated in FIG. 1, the redistribution layer 100 includes first insulating layers 20, first wiring layers 30, upper insulating layers 42 and 44, upper wiring layers 52, and terminal protection layers 54. The redistribution layer 100 includes chip connection terminals 60 and external connection terminals 70.

The upper wiring layers 52 are provided on the first wiring layers 30. The first wiring layers 30 are electrically connected to the upper wiring layers 52. One end of each of the first wiring layers 30 is electrically connected to each of the external connection terminals 70. The external connection terminals 70 are electrically connected to a non-illustrated external circuit. Each of the terminal protection layers 54 covers a portion of each of the upper wiring layers 52 exposed from the upper insulating layers 44. Each of the terminal protection layers 54 is electrically connected to each of the upper wiring layers 52. One end of each of the terminal protection layers 54 is electrically connected to each of the chip connection terminals 60. Each of the chip connection terminals 60 is electrically connected to each of terminals 202 of the semiconductor chip 200 described later.

The first insulating layers 20 and the upper insulating layers 42 and 44 are sequentially laminated, fill spaces between the wiring layers (spaces between the first wiring layers 30, spaces between the first wiring layers 30 and the upper wiring layers 52, and the like), and insulate between the wiring layers.

In the present embodiment, the first wiring layers 30, the upper wiring layers 52, and the terminal protection layers 54 connected in a predetermined wiring pattern are formed inside the laminated first insulating layers 20 and upper insulating layers 42 and 44. The redistribution layer 100 does not necessarily need to include the terminal protection layers 54, the chip connection terminals 60, and the external connection terminals 70.

As illustrated in FIG. 2, the semiconductor device 300 includes the redistribution layer 100, the semiconductor chip 200, and a mold resin layer 210. The semiconductor chip 200 is mounted on the redistribution layer 100. Each of the terminals 202 of the semiconductor chip 200 is electrically connected to each of the chip connection terminals 60 of the redistribution layer 100. The mold resin layer 210 covers the semiconductor chip 200 and the upper insulating layers 44, and seals the semiconductor chip 200.

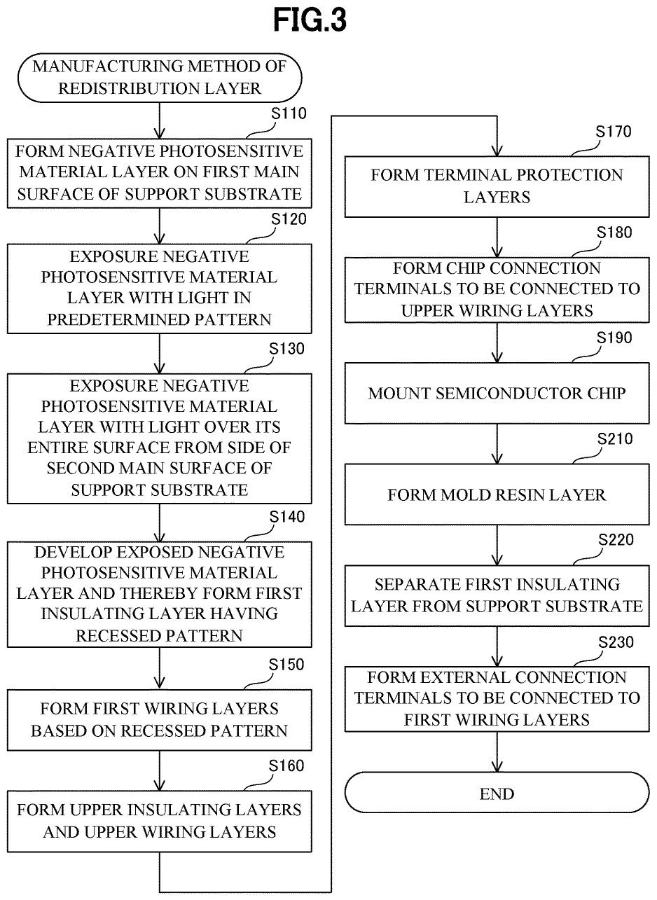

Next, the manufacturing method of the redistribution layer 100 is described. FIG. 3 is a flowchart illustrating the manufacturing method of the redistribution layer 100. The manufacturing method of the redistribution layer 100 includes a photosensitive layer forming step (step S110) of forming a negative photosensitive material layer 22 on a first main surface 10a of a support substrate 10, a first exposure step (step S120) of exposing the negative photosensitive material layer 22 with light in a predetermined pattern, a second exposure step (step S130) of exposing the negative photosensitive material layer 22 with light over its entire surface from the side of a second main surface 10b of the support substrate 10, a development step (step S140) of developing the exposed negative photosensitive material layer 22 to form the first insulating layer 20 having a recessed pattern 26, and a first wiring layer forming step (step S150) of forming the first wiring layers 30 based on the recessed pattern 26.

The manufacturing method of the redistribution layer 100 further includes an upper layer forming step (step S160) of forming the upper insulating layers 42 and 44 and the upper wiring layers 52, a terminal protection layer forming step (step S170) of forming the terminal protection layers 54, a chip connection terminal forming step (step S180) of forming the chip connection terminals 60, a mounting step (step S190) of mounting the semiconductor chip 200, a mold forming step (step S210) of forming the mold resin layer 210, a separation step (step S220) of separating the first insulating layer 20 from the support substrate 10, and an external connection terminal forming step (step S230) of forming the external connection terminals 70.

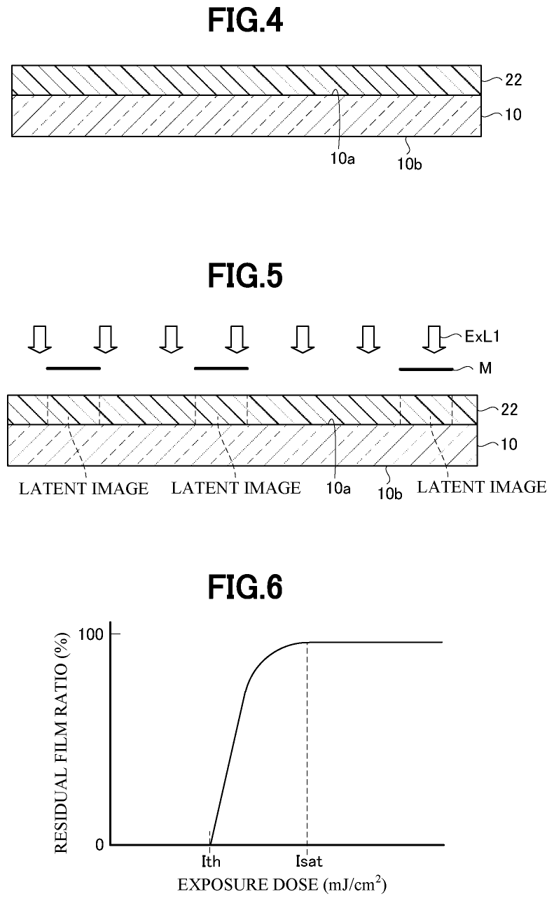

In the photosensitive layer forming step (step S110), as illustrated in FIG. 4, the negative photosensitive material layer 22 is formed on the first main surface 10a of the light-transmitting support substrate 10. In one example, the support substrate 10 is implemented as a glass substrate. The negative photosensitive material layer 22 is formed of a negative photosensitive material (for example, a photosensitive polyimide-based material) having insulating properties. The negative photosensitive material may be liquid or dry film. When the negative photosensitive material is liquid, the negative photosensitive material layer 22 is formed on the first main surface 10a of the support substrate 10 through spin coating, slit coating, or the like. The negative photosensitive material layer 22 formed on the first main surface 10a of the support substrate 10 may be prebaked.

In the first exposure step (step S120), as illustrated in FIG. 5, the negative photosensitive material layer 22 formed on the first main surface 10a of the support substrate 10 is exposed with exposure light ExL1 in a predetermined pattern from the side of the negative photosensitive material layer 22 by using masks M.

Here, an exposure dose for exposing the negative photosensitive material layer 22 is described. FIG. 6 illustrates an exposure sensitivity curve representing a residual film rate after development with respect to the exposure dose for the negative photosensitive material. The residual film ratio of the negative photosensitive material after development is a ratio of a film thickness of the negative photosensitive material after development to a film thickness of the negative photosensitive material before development. For the negative photosensitive material, the residual film ratio increases from zero when the exposure dose exceeds an exposure dose Ith, and saturates when the exposure dose reaches an exposure dose Isat. In other words, when the negative photosensitive material is exposed with light at an exposure dose exceeding the exposure dose Ith, solubility of the negative photosensitive material in a developer gradually decreases. When the negative photosensitive material is exposed with at an exposure dose exceeding the exposure dose Isat, the negative photosensitive material becomes insoluble in the developer. Herein, the exposure dose Ith is referred to as a threshold exposure dose Ith, and the exposure dose Isat is referred to as a saturation exposure dose Isat.

In the first exposure step (step S120), the negative photosensitive material layer 22 is preferably exposed with light at an exposure dose I1 that is greater than or equal to the saturation exposure dose Isat (that is, an exposure dose that saturates the residual film ratio).

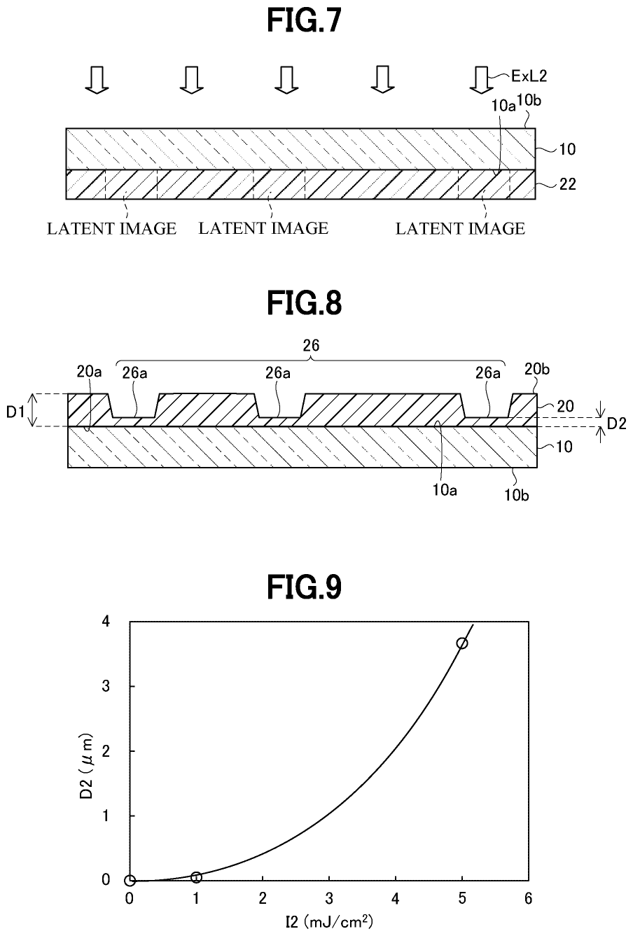

In the second exposure step (step S130), as illustrated in FIG. 7, the negative photosensitive material layer 22 exposed with light in the first exposure step (step S120) is exposed with exposure light ExL2 over its entire surface from the side of the second main surface 10b of the support substrate 10 that is opposite to the first main surface 10a. In the second exposure step, the negative photosensitive material layer 22 is exposed with light at an exposure dose I2 that is greater than or equal to the threshold exposure dose Ith and less than the saturation exposure dose Isat.

In the development step (step S140), as illustrated in FIG. 8, the negative photosensitive material layer 22 exposed with light in the first exposure step (step S120) and the second exposure step (step S130) is developed using a developer to form the first insulating layer 20 on the first main surface 10a of the support substrate 10. The first insulating layer 20 has the recessed pattern 26 on a second main surface 20b that is opposite to a first main surface 20a opposing the first main surface 10a of the support substrate 10. The recessed pattern 26 corresponds to the predetermined pattern in which the negative photosensitive material layer 22 has been exposed with light in the first exposure step (step S120). The recessed pattern 26 includes recesses 26a.

In the present embodiment, the exposure dose I1 in the first exposure step (step S120) is greater than or equal to the saturation exposure dose Isat, and the exposure dose I2 in the second exposure step (step S130) is greater than or equal to the threshold exposure dose Ith and less than the saturation exposure dose Isat. Therefore, the first main surface 20a of the first insulating layer 20 is in contact with the first main surface 10a of the support substrate 10 over its entire surface, and the recessed pattern 26 is formed on the second main surface 20b of the first insulating layer 20.

A thickness D1 of the first insulating layer 20 at a position where the recesses 26a are not formed is, for example, 10 μm to 20 μm. In order to facilitate removal of portions of the first insulating layer 20 located below the recesses 26a in the external connection terminal forming step (step S230) described later, a thickness D2 of the first insulating layer 20 at a position where each of the recesses 26a is formed preferably satisfies 0<D2≤1 μm.

As illustrated in FIG. 9, the thickness D2 can be controlled by changing the exposure dose I2 in the second exposure step (step S130). FIG. 9 illustrates the relationship between the exposure dose I2 in the second exposure step (step S130) and the thickness D2 when the development step (step S140) is performed with the thickness of the negative photosensitive material layer 22 set to 13.7 μm and the exposure dose I1 in the first exposure step (step S120) set to 200 mJ/cm².

Meanwhile, when the first insulating layer 20 having the recessed pattern 26 on the second main surface 20b is formed of a positive photosensitive material, the positive photosensitive material having a thickness of 10 μm to 20 μm is exposed with light and, as such, the exposure dose of exposure light to be irradiated to the positive photosensitive material increases. In order to set the thickness D2 to satisfy 0<D2≤1 μm, fine control of the exposure dose is required within a large exposure dose range. That is, control of the residual film ratio is difficult when the positive photosensitive material is used. Therefore, it is difficult to form the first insulating layer 20 having the recessed pattern 26 on the second main surface 20b from a positive photosensitive material with high reproducibility.

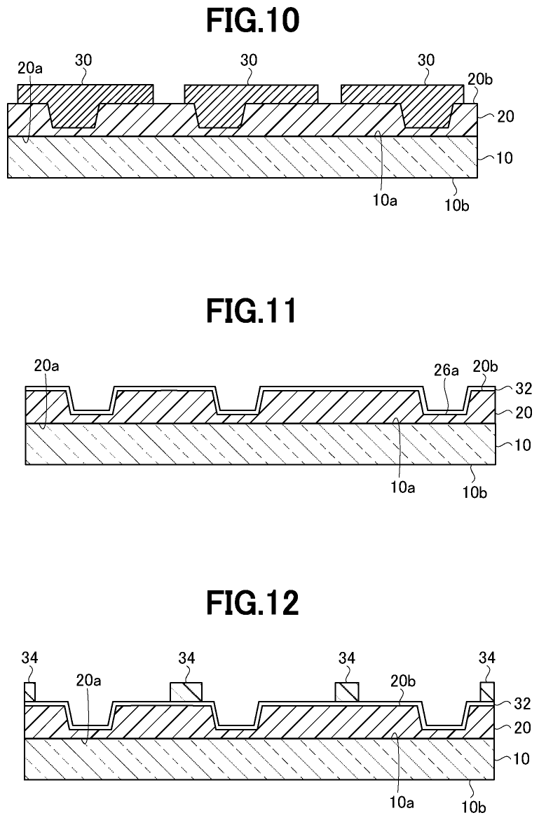

In the first wiring layer forming step (step S150), as illustrated in FIG. 10, the first wiring layers 30 are formed on the second main surface 20b of the first insulating layer 20 based on the recessed pattern 26. The first wiring layers 30 are formed of copper (Cu), nickel (Ni), titanium (Ti), or the like.

For example, the first wiring layers 30 are formed through electrolytic plating. Specifically, as illustrated in FIG. 11, a seed layer 32 is first formed on the second main surface 20b of the first insulating layer 20 (step S151). The seed layer 32 is formed of copper, nickel, titanium, or the like through spattering. In FIG. 11 and the subsequent figures, a hatching of the seed layer 32 is omitted for ease of understanding.

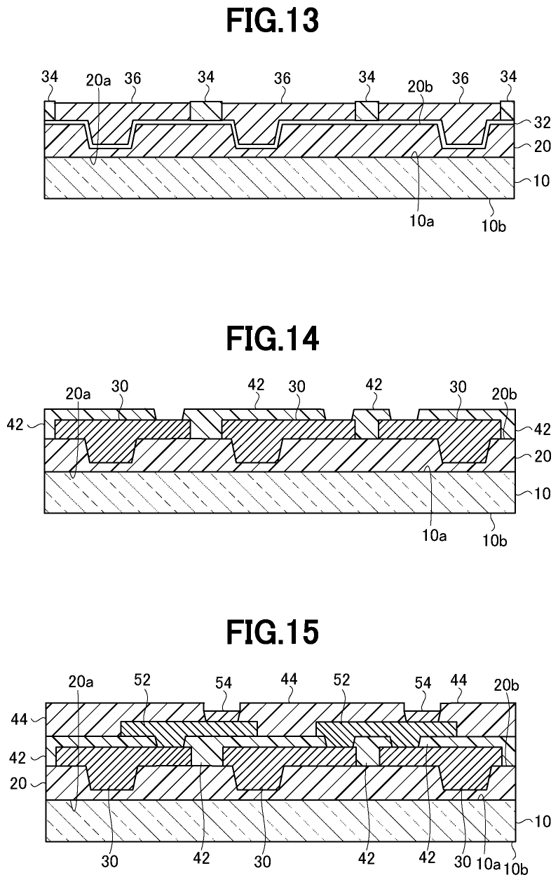

Next, as illustrated in FIG. 12, resist layers 34 having a pattern corresponding to the first wiring layers 30 are formed on the seed layer 32 (step S152). The resist layers 34 are formed by application, exposure, and development of a known resist. As illustrated in FIG. 13, electrolytic plating layers 36 are formed on the seed layer 32 through a known electrolytic plating. The resist layers 34 are then removed, and excess portions of the seed layer 32 exposed in the portions where the resist layers 34 have been removed are removed from the second main surface 20b of the first insulating layer 20 through etching (Step S153). Thus, the first wiring layers 30 can be formed.

In the upper layer forming step (step S160), the upper insulating layers 42, the upper wiring layers 52, and the upper insulating layers 44 are sequentially formed on the first insulating layer 20 and the first wiring layers 30. As illustrated in FIG. 14, the upper insulating layers 42 are first formed (step S161). Specifically, a photosensitive insulating material layer (not illustrated) is formed on the first insulating layer 20 and the first wiring layers 30, the photosensitive insulating material layer is then exposed with light, and the exposed photosensitive insulating material layer is developed to form the upper insulating layers 42. The material forming the upper insulating layers 42 (photosensitive insulating material layer) may be the same as the material forming the first insulating layer 20.

Next, the upper wiring layers 52 are formed through the same steps as steps S151 to S153 (step S162), and the upper insulating layers 44 are further formed (step S163). As with the upper insulating layers 42, a photosensitive insulating material layer is formed, the photosensitive insulating material layer is then exposed with light, and the exposed photosensitive insulating material layer is developed to form the upper insulating layers 44. Thus, the upper insulating layers 42 and 44 and the upper wiring layers 52 can be formed on the first insulating layer 20 and the first wiring layers 30. The material forming the upper insulating layers 44 (photosensitive insulating material layer) may be the same as the material forming the first insulating layer 20 or the upper insulating layers 42.

In the terminal protection layer forming step (step S170), as illustrated in FIG. 15, the terminal protection layers 54 to be connected to the upper wiring layers 52 are formed. Specifically, the terminal protection layers 54 are formed by an electroless Ni immersion gold (ENIG) treatment, an electroless Ni electroless palladium immersion gold (ENEPIG) treatment, or the like.

In the chip connection terminal forming step (step S180), the chip connection terminals 60 to be connected to the terminal protection layers 54 are formed. The chip connection terminals 60 are formed of solder through a known method.

In the mounting step (step S190), each of the terminals 202 of the semiconductor chip 200 is connected to each of the chip connection terminals 60, and the semiconductor chip 200 is mounted on the upper insulating layers 44. Specifically, the semiconductor chip 200 is positioned on the upper insulating layers 44, and the terminals 202 of the semiconductor chip 200 are then soldered to the chip connection terminals 60, for example, through a reflow method, to mount the semiconductor chip 200 on the upper insulating layers 44.

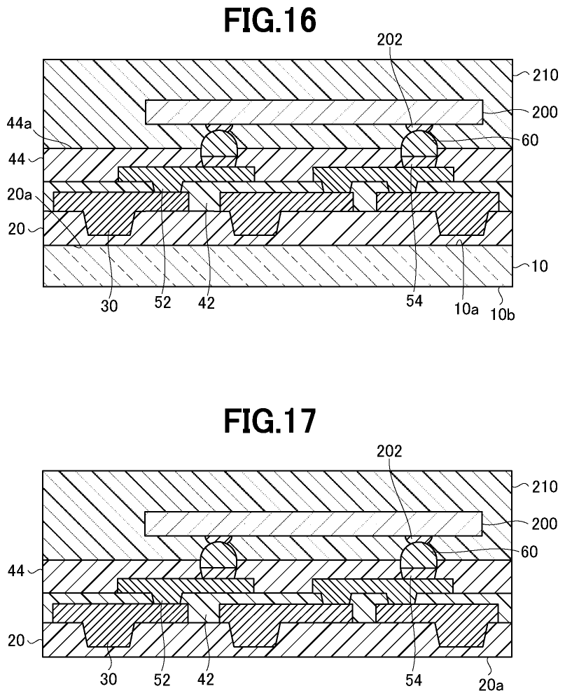

In the mold forming step (step S210), as illustrated in FIG. 16, the mold resin layer 210 covering the semiconductor chip 200 and main surfaces 44a of the upper insulating layers 44 is formed. In one example, the mold resin layer 210 is formed of epoxy resin.

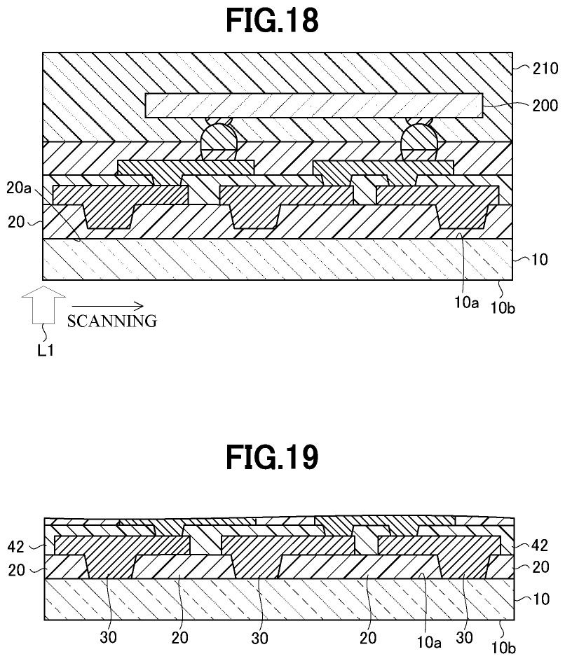

In the separation step (step S220), the first insulating layer 20 is irradiated with light L1 to be absorbed by the first insulating layer 20 from the side of the second main surface 10b of the support substrate 10 to separate the first insulating layer 20 from the support substrate 10 (FIG. 17). Specifically, as illustrated in FIG. 18, the first insulating layer 20 is separated from the support substrate 10 by laser lift-off in which laser light L1 (for example, having a wavelength of 355 nm) to be absorbed by the first insulating layer 20 is irradiated onto the first insulating layer 20 from the side of the second main surface 10b of the support substrate 10 while the laser light L1 is being scanned. In the laser lift-off, the interface between the support substrate 10 (first main surface 10a) and the first insulating layer 20 (first main surface 20a) is ablated by the laser light L1, causing the first insulating layer 20 to be separated from the support substrate 10.

In the present embodiment, the first main surface 20a of the first insulating layer 20 is in contact with the first main surface 10a of the support substrate 10 over its entire surface. Since the first insulating layer 20 undergoes ablation at low laser energy, the first insulating layer 20 can be readily separated from the support substrate 10. Further, since there is no need to provide a release layer to separate the first insulating layer 20 from the support substrate 10, the manufacturing cost can be reduced.

Meanwhile, as illustrated in FIG. 19, in a configuration (hereinafter, referred to as a comparative example) in which the first main surface 10a of the support substrate 10 is in contact with the first insulating layers 20 and the first wiring layers 30, interfaces are present between the support substrate 10 and the first insulating layers 20, and between the support substrate 10 and the first wiring layers 30. At the interfaces where the first wiring layers 30 are formed directly on the support substrate 10, the first wiring layers 30 and the support substrate 10 are firmly adhered to each other. As described above, the interfaces between the support substrate 10 and the first insulating layers 20 can be separated by low laser energy, while it is difficult to separate the interfaces between the support substrate 10 and the first wiring layers 30 by low laser energy. High laser energy is required to separate the first wiring layers 30 from the support substrate 10. When the interfaces between the support substrate 10 and the first insulating layers 20 and the interfaces between the support substrate 10 and the first wiring layers 30 are separated by high laser energy, significant damage occurs at the interfaces between the support substrate 10 and the first insulating layers 20. Therefore, it is difficult to separate the first insulating layers 20 and the first wiring layers 30 from the support substrate 10 by the laser lift-off. Note that layers above the upper insulating layers 42 are omitted in FIG. 19.

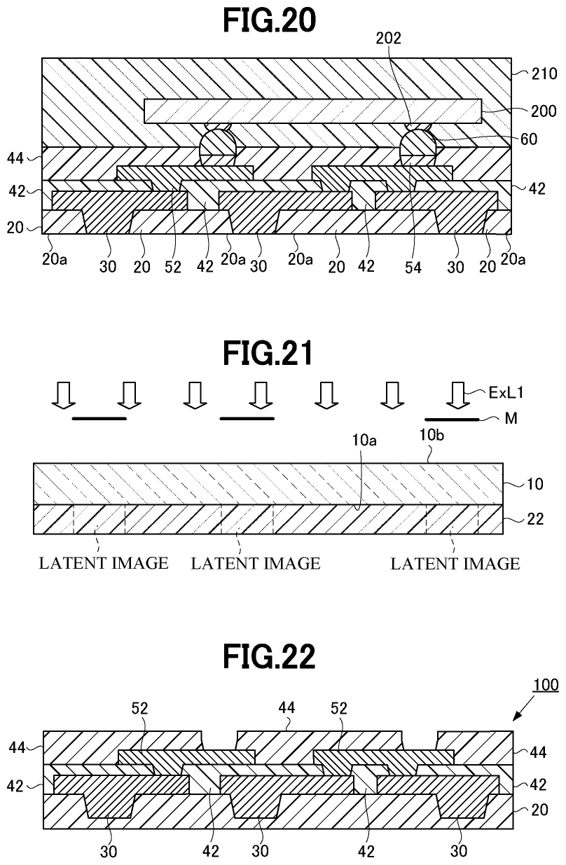

In the external connection terminal forming step (step S230), at least a portion of each of the first wiring layers 30 is exposed from the first insulating layer 20, and the external connection terminals 70 to be connected to the exposed first wiring layers 30 are formed. Specifically, as illustrated in FIG. 20, portions of the first insulating layer 20 are removed, for example, by oxygen ashing from the side of the first main surface 20a to expose the first wiring layers 30 (step S231). The external connection terminals 70 to be connected to the first wiring layers 30 are then formed (step S232). The external connection terminals 70 are formed of solder through a known method.

The redistribution layer 100 can be manufactured as described above. The manufacturing method of the redistribution layer 100 of the present embodiment corresponds to a manufacturing method of the semiconductor device 300.

As described above, the first insulating layer 20 having the recessed pattern 26 on the second main surface 20b is formed such that the first main surface 20a is in contact with the first main surface 10a of the support substrate 10 over its entire surface. Thus, the manufacturing method of the redistribution layer 100 allows the redistribution layer 100 to be readily manufactured while reducing the manufacturing cost.

### Embodiment 2

In the first exposure step (step S120) of Embodiment 1, the negative photosensitive material layer 22 is exposed with light from the side of the negative photosensitive material layer 22 by using the masks M. The negative photosensitive material layer 22 may be exposed with light from the side of the second main surface 10b of the support substrate 10 by using the mask M.

A manufacturing method of the redistribution layer 100 of the present embodiment is the same as the manufacturing method of the redistribution layer 100 of Embodiment 1, except for the first exposure step (step S120). Here, the first exposure step (step S120) of the present embodiment is described.

In the first exposure step (step S120) of the present embodiment, as illustrated in FIG. 21, the negative photosensitive material layer 22 formed on the first main surface 10a of the support substrate 10 is exposed with the exposure light ExL1 in the predetermined pattern from the side of the second main surface 10b of the support substrate 10 by using the masks M. As with Embodiment 1, the exposure dose I1 is preferably greater than or equal to the saturation exposure dose Isat (the exposure dose that saturates the residual film ratio).

In the present embodiment, the first insulating layer 20 having the recessed pattern 26 on the second main surface 20b is formed such that the first main surface 20a is in contact with the first main surface 10a of the support substrate 10 over its entire surface. Thus, the manufacturing method of the redistribution layer 100 allows the redistribution layer 100 to be readily manufactured while reducing the manufacturing cost.

### Embodiment 3

In Embodiment 1, the redistribution layer 100 is manufactured with the semiconductor chip 200 mounted thereon. The redistribution layer 100 includes the terminal protection layers 54, the chip connection terminals 60, and the external connection terminals 70.

The redistribution layer 100 does not necessarily need to be manufactured with the semiconductor chip 200 mounted thereon. Further, the redistribution layer 100 does not necessarily need to include the terminal protection layers 54, the chip connection terminals 60, and the external connection terminals 70.

As illustrated in FIG. 22, the redistribution layer 100 of the present embodiment does not include the terminal protection layers 54, the chip connection terminals 60, and the external connection terminals 70. The configuration of the redistribution layer 100 of the present embodiment is the same as that of the redistribution layer 100 of Embodiment 1, except that the redistribution layer 100 does not include the terminal protection layers 54, the chip connection terminals 60, and the external connection terminals 70, and that the first wiring layers 30 are not exposed from the first insulating layer 20.

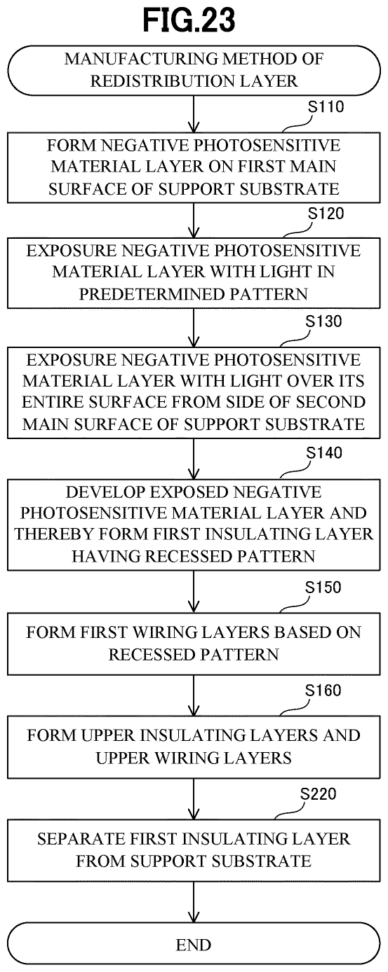

Next, a manufacturing method of the redistribution layer 100 of the present embodiment is described. FIG. 23 is a flowchart illustrating the manufacturing method of the redistribution layer 100 of the present embodiment. The manufacturing method of the redistribution layer 100 of the present embodiment includes the photosensitive layer forming step (step S110), the first exposure step (step S120), the second exposure step (step S130), the development step (step S140), the first wiring layer forming step (step S150), the upper layer forming step (step S160), and the separation step (step S220). Each step of the present embodiment is the same as that of Embodiment 1.

In the present embodiment, the first insulating layer 20 having the recessed pattern 26 on the second main surface 20b is formed such that the first main surface 20a is in contact with the first main surface 10a of the support substrate 10 over its entire surface. Thus, the manufacturing method of the redistribution layer 100 allows the redistribution layer 100 to be readily manufactured while reducing the manufacturing cost.

In the redistribution layer 100 of the present embodiment, at least a portion of each of the first wiring layers 30 may be exposed from the first insulating layer 20 by removing portions of the first insulating layer 20 from the side of the first main surface 20a.

### Modified Examples

The above-described embodiments may be modified in various manners within the gist of the present disclosure.

For example, the seed layer 32 formed in the first wiring layer forming step (step S150) may be formed from a single layer or from a plurality of layers.

In the embodiments, after the photosensitive layer forming step (step S110), the negative photosensitive material layer 22 is exposed with light in the first exposure step (step S120) and the second exposure step (step S130) in this order. In the manufacturing method of the redistribution layer 100, after the photosensitive layer forming step (step S110), the negative photosensitive material layer 22 may be exposed with light in the second exposure step (step S130) and the first exposure step (step S120) in this order.

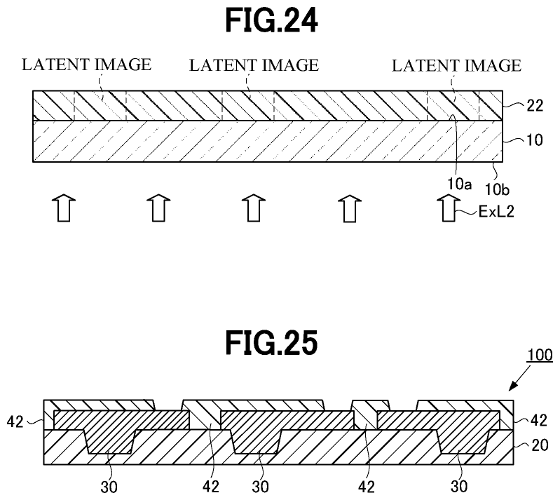

In the second exposure step (step S130) of the embodiments, the support substrate 10 is oriented upward on paper to exposure the negative photosensitive material layer 22 with the exposure light ExL2 over its entire surface from the side of the second main surface 10b of the support substrate 10 (FIG. 7). In the second exposure step (step S130), as illustrated in FIG. 24, the support substrate 10 may be oriented downward on paper to exposure the negative photosensitive material layer 22 with the exposure light ExL2 over its entire surface from the side of the second main surface 10b of the support substrate 10.

In the second exposure step (step S130) of the embodiments, the exposure dose I2 for exposing the negative photosensitive material layer 22 with light is preferably a smaller exposure dose (an exposure dose closer to the threshold exposure dose Ith) within a range that is greater than or equal to the threshold exposure dose Ith and less than the saturation exposure dose Isat. This reduces the exposure intensity and, as such, allows the residual film ratio to be readily controlled by changing the exposure time, thereby improving time controllability.

The redistribution layer 100 of the embodiments includes the upper wiring layers 52 and the terminal protection layers 54. As illustrated in FIG. 25, the redistribution layer 100 may be formed from the first insulating layer 20, the first wiring layers 30, and the upper insulating layers 42. In this case, the manufacturing method of the redistribution layer 100 includes the photosensitive layer forming step (step S110), the first exposure step (step S120), the second exposure step (step S130), the development step (step S140), the first wiring layer forming step (step S150), a step of forming the upper insulating layers 42 (step S161), and the separation step (step S220).

The redistribution layer 100 may include two or more upper wiring layers.

Further, the redistribution layer 100 may be formed from the first insulating layer 20 and the first wiring layers 30.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

1. A manufacturing method of a redistribution layer comprising:
a photosensitive layer forming step of forming a negative photosensitive material layer on a first main surface of a light-transmitting support substrate;
a first exposure step of exposing the negative photosensitive material layer formed on the first main surface of the support substrate with light in a predetermined pattern;
a second exposure step of exposing the negative photosensitive material layer formed on the first main surface of the support substrate with light over an entire surface of the negative photosensitive material layer from a side of a second main surface of the support substrate opposite to the first main surface;
a development step of developing the negative photosensitive material layer exposed with light in the first exposure step and the second exposure step, and thereby forming a first insulating layer on the first main surface of the support substrate, the first insulating layer having a recessed pattern corresponding to the predetermined pattern on a second main surface of the first insulating layer, the second main surface of the first insulating layer being opposite to a first main surface of the first insulating layer opposing the first main surface of the support substrate;
a first wiring layer forming step of forming, based on the recessed pattern, a first wiring layer on the second main surface of the first insulating layer; and
a separation step of irradiating the first insulating layer with light to be absorbed by the first insulating layer from the side of the second main surface of the support substrate, and thereby separating, from the support substrate, the first insulating layer on which the first wiring layer is formed.

2. The manufacturing method of the redistribution layer according to claim 1, wherein
in the first exposure step, in an exposure sensitivity curve representing a residual film ratio after development with respect to an exposure dose for the negative photosensitive material layer, the negative photosensitive material layer formed on the first main surface of the support substrate is exposed with light at an exposure dose greater than or equal to an exposure dose saturating the residual film ratio, and
in the second exposure step, in the exposure sensitivity curve, the negative photosensitive material layer formed on the first main surface of the support substrate is exposed with light at an exposure dose greater than an exposure dose resulting in the residual film rate greater than zero and less than the exposure dose saturating the residual film ratio.

3. The manufacturing method of the redistribution layer according to claim 1, wherein
in the first exposure step, the negative photosensitive material layer formed on the first main surface of the support substrate is exposed with light in the predetermined pattern from a side of the negative photosensitive material layer.

4. The manufacturing method of the redistribution layer according to claim 1, wherein
in the first exposure step, the negative photosensitive material layer formed on the first main surface of the support substrate is exposed with light in the predetermined pattern from the side of the second main surface of the support substrate.

5. The manufacturing method of the redistribution layer according to claim 1, further comprising:
an upper layer forming step of sequentially forming an upper insulating layer and an upper wiring layer on the first wiring layer, the upper wiring layer being connected to the first wiring layer.

6. The manufacturing method of the redistribution layer according to claim 5, further comprising:
a mounting step of mounting a semiconductor chip to be connected to the upper wiring layer.

7. The manufacturing method of the redistribution layer according to claim 1, further comprising:
an external connection terminal forming step of exposing at least a portion of the first wiring layer from the first insulating layer separated from the support substrate, and forming an external connection terminal to be connected to the exposed portion of the first wiring layer.
